(19) United States
(12) Patent Application Publication
(10) Pub. No.: US 2006/0163619 A1
(43) Pub. Date: Jul. 27, 2006

(54) Solid-state imaging device and method for producing solid-state imaging device

(76) Inventor: Kazushi Wada, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/539,133

(22) PCT Filed: Dec. 5, 2003
(86) PCT No.: PCT/JP03/15596

§ 371 Date: Jun. 15, 2005

(30) Foreign Application Priority Data
Dec. 16, 2002 (JP) 2002-363261

(51) Int. Cl. H01L 27/148; H01L 21/00

(52) U.S. Cl. 257/232; 257/239; 438/48; 257/E31.078

(57) ABSTRACT

A solid state image pickup device in which an image pickup region composed of a plurality of light-receiving pixel portions 1 and a transfer register 2 for transferring in one direction the signal charges accumulated in the light-receiving pixel portions 1 is formed on the face layer portion side of a semiconductor substrate and which prevents the mixing of signals between the adjacent signals even in the case where an overflow barrier is formed at a deep position for the purpose of enhancing the sensitivity per unit area, wherein barrier regions 15 each being an impurity region continuing in a direction orthogonal to the transfer direction of the transfer register 2 over the entire region of the image pickup region are each formed at a position corresponding to a position between the light-receiving pixel portions 1 adjacent to each other in the transfer direction, whereby a sufficient potential barrier is formed and the mixing of signals is thereby prevented.

### TECHNICAL FIELD

The present invention relates to a solid state image pickup device and a method of manufacturing a solid state image pickup device, preferable for use for a CCD (Charge Coupled Device) or the like.

### BACKGROUND ART

In recent year, attendant on the reduction in size of the unit cell in solid state image pick devices, development of a technology for enhancing sensitivity per unit area has been urgently required. As a means for meeting the requirement, for example, in a CCD type solid state image pickup device using an n-type semiconductor substrate, there may be contemplated an approach in which the so-called overflow barrier usually formed at a depth of about 3 μm from the surface of the substrate is formed at a deeper position (for example, in the range of 5 to 10 μm) so as to extend the depletion layer, thereby enhancing the sensitivity. It should be noted here, however, that if the overflow barrier is formed at a deep position, holes accumulated in the overflow barrier region would not be discharged, so that a phenomenon of saturated charge quantity or the so-called shading would be generated. In view of this, conventionally, a technology has been proposed in which, as for example shown in FIG. 8A, in a CCD type solid state image pickup device, a P-type impurity region 23 is formed between pixels 22a and 22b adjacent to each other in a direction parallel to a vertical transfer register 21 so as thereby to alleviate the potential barrier and to permit the holes accumulated in the overflow barrier region to be easily discharged to the substrate surface (see, for example, Japanese Patent Laid-open No. Hei 11-289076).

Meanwhile, in the above-mentioned conventional technology, since the P-type impurity region 23 is formed between the pixels 22a and 22b, not only the holes in the overflow barrier region can be discharged to the substrate surface but also the barrier between the pixels 22a and 22b can be enlarged by the P-type impurity region 23, making it difficult for the mixing of signals between the pixels 22a and 22b adjacent to each other in the vertical direction to be generated. However, the P-type impurity region 23 in the past is formed only at a part of the portion between the pixels 22a and 22b as shown for example in FIG. 8B, so that a sufficient potential barrier cannot be formed, and the mixing of signals cannot necessarily be prevented.

In order to form the P-type impurity region 23, it is necessary to implant ions, for example, boron (B) ions, into an n-type semiconductor substrate. The P-type impurity region 23 in the past, however, is provided principally for discharging the holes, so that it suffices for the P-type impurity region 23 to be able to alleviate the potential barrier; from this point of view, the P-type impurity region 23 has been formed at a depth comparable to the depth of the vertical transfer register 21 by ion implantation at an energy of several tens of kilo electron volt (KeV), for example. Therefore, in order not to influence the potential of the vertical transfer register 21, i.e., in order not to hamper the transferring action in the vertical transfer register 21, it is necessary to secure a certain distance (to provide a gap) between the P-type impurity region 23 and the vertical transfer register 21. In the conventional technology, therefore, a sufficient potential barrier cannot be formed between the pixels 22a and 22b, so that it may be impossible to prevent the mixing of signals.

Accordingly, it is an object of the present invention to provide a solid state image pickup device and a method of manufacturing a solid state image pickup device by which it is possible to prevent the mixing of signals between adjacent pixels even in the case where the overflow barrier is formed at a deep position for the purpose of enhancing the sensitivity per unit area.

### DISCLOSURE OF INVENTION

The present invention pertains to a solid state image pickup device devised for attaining the above object. Specifically, according to the present invention, there is provided a solid state image pickup device having an image pickup region including a plurality of photo-sensors and a transfer register for transferring signal charges accumulated in the photo-sensors, the image pickup region formed on the face layer side of a substrate, wherein the solid state image pickup device further includes an impurity region portion formed continuously in a direction orthogonal to the transfer direction of the transfer register over roughly the entire region of the image pickup region, the impurity region portion provided at a position corresponding to a position between the photo-sensors adjacent to each other along the transfer direction of the transfer register in the semiconductor substrate.

In the solid state image pickup device configured as above, the photo-sensors each accumulate therein signal charges in an amount according to incident light by photo-electric conversion. In addition, the transfer register receive and transfer the signal charges accumulated in the photo-sensors. Here, the transfer register is a transfer register constituting the image pickup region, and, for example in a CCD type solid state image pickup device in which a plurality of photo-sensors are arranged in two-dimensional matrix pattern, a vertical transfer register corresponds to the transfer register constituting the image pickup region.

In the solid state image pickup device configured as above, the impurity region portion is formed at a position corresponding to a position between the photo-sensors adjacent to each other along the transfer direction of the transfer register. The impurity region portion is composed of an impurity region; for example, where the semiconductor substrate is either one of p-type and an n-type, the impurity region is formed by use of an impurity of either one of p-type and n-type which is different from the type of the semiconductor substrate. Besides, the position corresponding to a position between the photo-sensors includes not only a position which is located at roughly the same depth as each photo-sensor and located between the photo-sensors but also a position which is deeper than each photo-sensor, is not located between the photo-sensors but is located between the photo-sensors in plan view as viewed from the face layer portion side of the semiconductor substrate.

Further, the impurity region portion is continuously formed in a direction orthogonal to the transfer direction of the transfer register, over roughly the entire region of the image pickup region, i.e., over the range from one end (inclusive of the vicinity thereof) to the other end (inclusive of the vicinity thereof) of the image pickup region. In other words, for example in the case where the transfer register is a vertical transfer register, the impurity region portion is continuously formed in a horizontal direction. According to the solid state image pickup device configured as above, therefore, the impurity region portion is continuously formed, so that a sufficient potential barrier can be formed between the photo-sensors, and the mixing of signals can be prevented.

### BRIEF DESCRIPTION OF DRAWINGS

FIG. 1 is a schematic diagram showing the general configuration of a solid state image pickup device to which the present invention is applied;

FIG. 2A is a schematic diagram showing an exemplary configuration of a major part in a first embodiment of the solid state image pickup device according to the present invention, and is a plan view;

FIG. 2B is a schematic diagram showing the exemplary configuration of the major part in the first embodiment of the solid state image pickup device according to the present invention, and is an A-A sectional view;

FIG. 3A is a schematic diagram showing an exemplary configuration of a major part in a second embodiment of the solid state image pickup device according to the present invention, and is a plan view;

FIG. 3B is a schematic diagram showing the exemplary configuration of the major part in the second embodiment of the solid state image pickup device according to the present invention, and is a B-B sectional view;

FIG. 4 is a schematic diagram showing an exemplary configuration of a major part in a third embodiment of the solid state image pickup device according to the present invention, and is a sectional view along line C-C of FIG. 2A;

FIG. 5 is a schematic diagram showing an exemplary configuration of a major part in a fourth embodiment of the solid state image pickup device according to the present invention, and is a sectional view along line D-D of FIG. 2A;

FIG. 6A is a schematic diagram showing an exemplary configuration of a major part in a fifth embodiment of the solid state image pickup device according to the present invention, and is a plan view;

FIG. 6B is a schematic diagram showing the exemplary configuration of the major part in the fifth embodiment of the solid state image pickup device according to the present invention, and is an E-E sectional view;

FIG. 7A is a schematic diagram showing an exemplary configuration of a major part in a sixth embodiment of the solid state image pickup device according to the present invention, and is a plan view;

FIG. 7B is a schematic diagram showing the exemplary configuration of the major part in the sixth embodiment of the solid state image pickup device according to the present invention, and is an F-F sectional view;

FIG. 7C is a schematic diagram showing the exemplary configuration of the major part in the sixth embodiment of the solid state image pickup device according to the present invention, and is a G-G sectional view;

FIG. 8A is a schematic diagram showing the exemplary configuration of a major part of a solid state image pickup device according to the related art, and is a plan view; and

FIG. 8B is a schematic diagram showing the exemplary configuration of the major part of the solid state image pickup device according to the related art, and is an H-H sectional view.

### BEST MODE FOR CARRYING OUT THE INVENTION

Now, the solid state image pickup device according to the present invention will be described below, based on the drawings. Here, description will be made by taking as an example the case where the present invention is applied to a CCD type solid state image pickup device using an n-type semiconductor substrate.

### FIRST EMBODIMENT

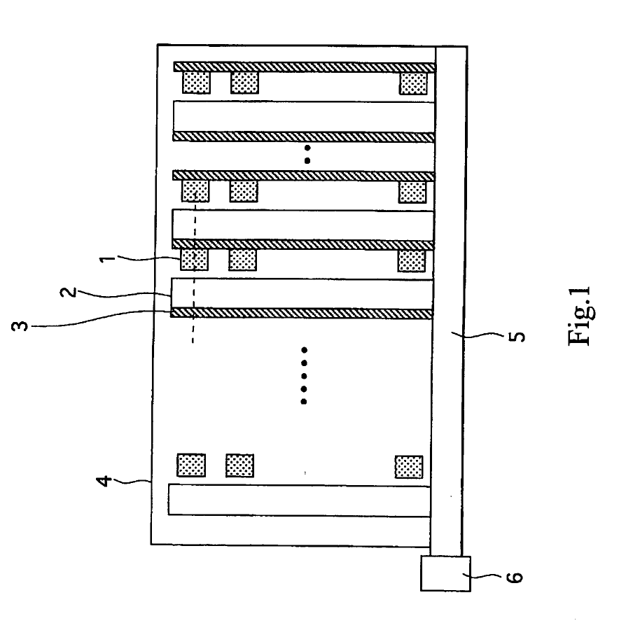

Here, a solid state image pickup device according to a first embodiment will be described. First, the general configuration of the solid state image pickup device will be described. FIG. 1 is a schematic diagram showing an exemplary general configuration of the solid state image pickup device to which the present invention is applied. As shown in the figure, the solid state image pickup device to be described here includes a plurality of photo-sensors 1 arranged in a two-dimensional matrix pattern, vertical transfer registers 2 arranged on the basis of each column in the two-dimensional arrangement, and channel stops 3 arranged along the vertical transfer registers 2, and they constitute an image pickup region 4. Of the solid state image pickup device, the photo-sensors 1 are for accumulating signal charges by photo-electric conversion, and function as photo-sensors in the present invention. The vertical transfer registers 2 are for transferring the signal charges accumulated in each photo-sensor 1, in the vertical direction in the two-dimensional arrangement. The channel stops 3 are for separation between each photo-sensor 1 and the vertical transfer register 2.

In addition to the image pickup region 4 as above, the solid state image pickup device includes a horizontal transfer register 5 arranged at one end of the image pickup region 4, and an output portion 6 connected to the last stage of the horizontal transfer register 5. The horizontal transfer register 5 receives signal charges from each vertical transfer register 2, and transfer the signal charges in a horizontal direction in the two-dimensional arrangement. The output portion 6 is composed of a floating diffusion amplifier, other processing circuits or the like, and is for applying a predetermined signal processing to the signal charge outputted from the horizontal transfer register 5.

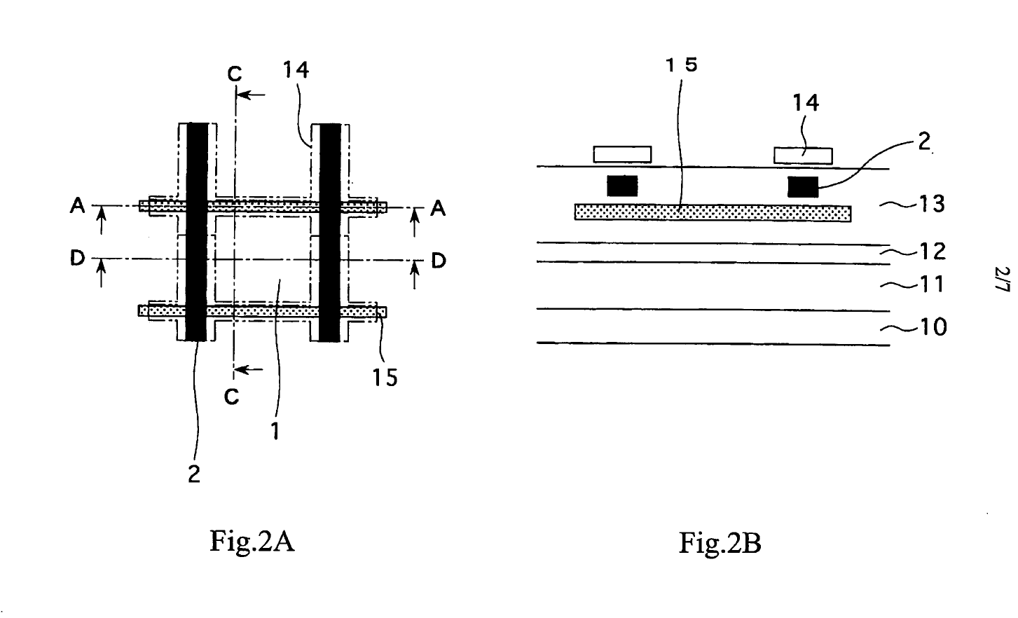

Next, the sectional structure of the solid state image pickup device having the above-mentioned plan view structure will be described. FIGS. 2A and 2B are schematic diagrams showing an exemplary configuration of a major part in the first embodiment of the solid state image pickup device according to the present invention. As shown in the figures, the solid state image pickup device has a pixel structure in which an n⁻ epitaxial layer 11, an overflow barrier region 12 composed of a p-type well layer, a high-resistance semiconductor region 13 lower than the overflow barrier region 12 in p-type impurity concentration, the photo-sensor 1, the vertical transfer transistor 2 and the like are sequentially laminated on an n-type silicon (hereinafter referred to as “Si”) substrate 10. Specifically, the above-mentioned photo-sensors 1 and vertical transfer registers 2 and the like are formed on the face layer portion side of the semiconductor substrate constituting the solid state image pickup device. On the upper side of the vertical transfer register 2, a transfer electrode 14 for causing the vertical transfer register 2 to transfer the signal charge is formed.

In the sectional structure as above, the overflow barrier region 12 may not necessarily be composed of the p-type well layer. In other words, where the type of the impurity semiconductor in the Si substrate 10 is a first conduction type and the type of the impurity semiconductor in the overflow barrier layer 12 is a second conduction type, it suffices for the second conduction type to be of a type different from the first conduction type. Therefore, where the Si substrate 10 is of p-type, the overflow barrier region 12 is composed of an n-type well layer. In addition, a semiconductor region 13 formed on the overflow barrier region 12 may not necessarily be composed of the p-type impurity, and it suffices for the semiconductor region 13 to be of any of the first conduction type, the second conduction type, and an intrinsic type.

Meanwhile, the solid state image pickup device being described here is conspicuously characterized by having impurity region portions 15 formed in the semiconductor region 13. Like the overflow barrier region 12, the impurity region portions 15 are comprised of an impurity of the second conduction type, i.e., for example, a p-type impurity region, and, preferably, the impurity concentration in the impurity region portions 15 is higher than that in the overflow barrier region 12. As shown in FIG. 2A, the impurity region portion 15 is located at a position corresponding to a position between the photo-sensors 1 adjacent to each other in the vertical direction of the two-dimensional arrangement, and, as shown in FIG. 2B, it is continuously formed in the horizontal direction of the two-dimensional arrangement over roughly the entire region of the image pickup region 4. Here, the position corresponding to a position between the photo-sensors 1 includes the meaning of a position which is between the photo-sensors 1, namely, a position which is at roughly the same depth as the photo-sensors 1 and located between the photo-sensors 1, and a position which is deeper than the photo-sensors 1 so as not to be located between the photo-sensor 1 but which appears between the photo-sensors 1 when viewed on a plan view basis from the face layer portion side of the semiconductor substrate. Besides, the expression “roughly the entire region of the image pickup region 4” means the range from one end (inclusive of the vicinity thereof) to the other end (inclusive of the vicinity thereof) of the image pickup region 4.

Further, the impurity region portion 15 is formed at a position deeper than the vertical transfer registers 2, as viewed from the face layer portion side of the semiconductor substrate. This ensures that the impurity region portion 15 avoids the formation positions of the vertical transfer registers 2 and is continued in the horizontal direction on the lower side of the formation positions. Besides, since the impurity region portion 15 is formed at the position corresponding to a position between the photo-sensors 1, the impurity region portions 15 are formed in the shape of stripes extending in the horizontal direction, as viewed on a plan view basis from the face layer portion side of the semiconductor substrate.

The impurity region portions 15 can be formed by implanting ions of, for example, boron (B), which is a p-type impurity, into the n-type Si substrate 10. It should be noted here that, in order to form the impurity region portions 15 at positions deeper than the vertical transfer registers 2, the implantation energy is not less than several hundreds of kilo electron volt. Further, for the impurity region portions 15 to continue in the horizontal direction, the ion implantation is carried out by utilizing patterning corresponding to the shape of stripes extending in the horizontal direction. Incidentally, the methods of producing the other portions may be the same as in the related art, and, therefore, description thereof is omitted here.

In the solid state image pickup device configured as above, the impurity region portions 15 are each formed at a position corresponding to a position between the photo-sensors 1 adjacent to each other in the vertical direction, and the impurity region portions 15 is each continuously formed in the horizontal direction over roughly the entire region of the image pickup region 4. Namely, the impurity region portion 15 as a barrier region is formed not at a part of the portion between pixels as in the related art but over the entire region of that portion. Therefore, a sufficient potential barrier can be formed between the photo-sensors 1 adjacent to each other in the vertical direction, and the mixing of signal charges in the vertical direction can be prevented. Therefore, according to the solid state image pickup device in this embodiment, the mixing of signal charges between the adjacent pixels can be prevented, even in the case where the overflow barrier region 12 is formed at a deep position for the purpose of enhancing the sensitivity per unit area.

Furthermore, according to the solid state image pickup device in this embodiment, the impurity region portions 15 are formed at positions deeper than the vertical transfer registers 2, so that the interference of their potential on the vertical transfer registers 2 can be precluded. Namely, a sufficient potential barrier can be formed between the photo-sensors 1 without hampering the transfer actions of the vertical transfer registers 2, and prevention of the mixing of signal charges in the vertical direction can be thereby contrived. Moreover, the impurity region portions 15 can be formed by simply implanting the ions of the p-type impurity into the deep positions and, in addition, the transfer electrodes 14 and the like configured in the same manner as in the related art can be utilized as they are, so that the favorable potential barrier can be easily realized without complication of the configuration.

In addition, in the solid state image pickup device in this embodiment, the impurity region portions 15 are formed in the semiconductor region 13, so that the potential barrier on the holes by the semiconductor region 13 in the range from the overflow barrier region 12 to the surface of the semiconductor substrate can be alleviated, and the holes accumulated in the overflow barrier region 12 can be discharged to the surface of the semiconductor substrate. Therefore, it is possible to obviate such problems as a phenomenon of saturated charge quantity, and generation of shading.

From the foregoing, it can be said that the solid state image pickup device in this embodiment is suitable for a reduction in size of solid state image pickup device without causing a lowering in picked-up image quality, since the mixing of signals between the adjacent pixels can be prevented while enhancing the sensitivity per unit area, and such problems as shading can be prevented from occurring.

While description has been made by taking as an example the case where the impurity region portions 15 are formed at positions deeper than the vertical transfer registers in this embodiment, the impurity region portions 15 may, for example, be formed at positions shallower than the vertical transfer registers 2 insofar as the impurity region portions 15 are continuously formed in the horizontal direction, whereby the mixing of signal charges in the vertical direction can be prevented. The positions of the impurity region portions 15 are preferably deeper than the vertical transfer registers 2, but this layout is not limitative.

### SECOND EMBODIMENT

Now, a solid state image pickup device in a second embodiment will be described below. It should be noted here that only the difference between this embodiment and the above-described first embodiment will be described.

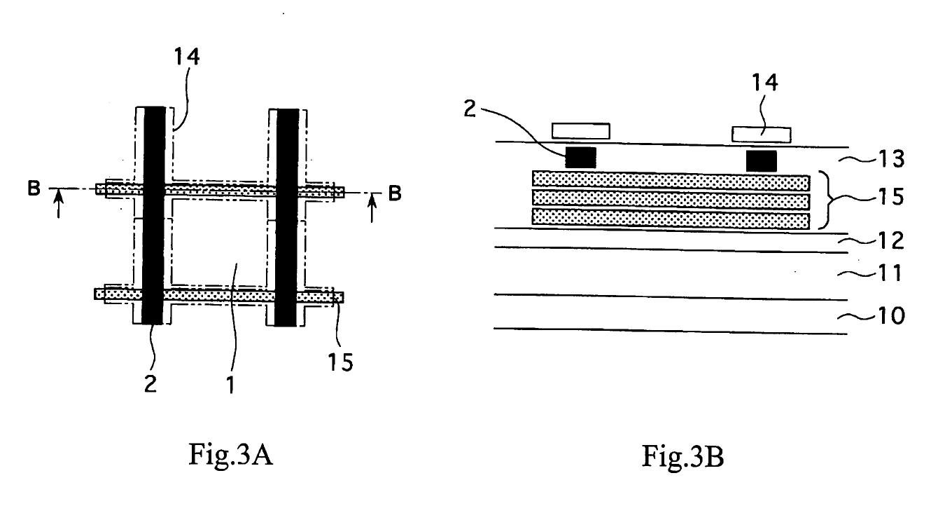

FIGS. 3A and 3B are schematic diagrams showing an exemplary configuration of a major part in the second embodiment of the solid state image pickup device according to the present invention. As shown in the figures, the solid state image pickup device described here has a configuration in which impurity region portions 15 are formed in a plurality of stages in the depth direction of the semiconductor substrate.

Such impurity region portions 15 can be formed by implanting the ions of a p-type impurity into the Si substrate 10 while appropriately changing the implantation energy, the implantation being separately conducted in a number of times corresponding to the number of the stages.

In the solid state image pickup device configured as above, the impurity region portions 15 continuing in the horizontal direction are formed in a plurality of stages, so that a potential barrier more satisfactory than that in the first embodiment can be formed between the photo-sensors 1 adjacent to each other in the vertical direction. Therefore, the mixing of signal charges between the adjacent pixels can be prevented more effectively than in the case of the first embodiment.

### THIRD EMBODIMENT

Now, a solid state image pickup device according to a third embodiment will be described below. It should be noted here that only the difference between this embodiment and the first or second embodiment will be described.

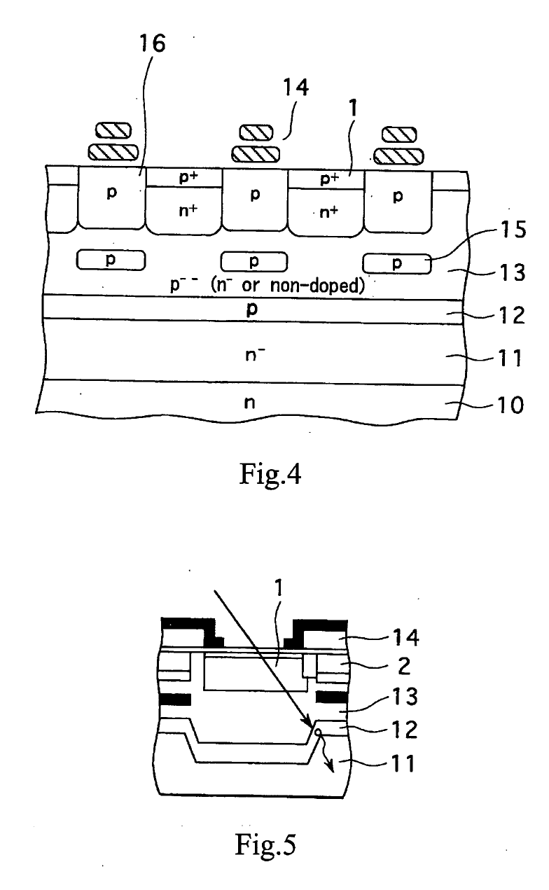

FIG. 4 is a schematic diagram showing an exemplary configuration of a major part in the third embodiment of the solid state image pickup device according to the present invention. As shown in the figure, the solid state image pickup device being described here has a configuration in which, separately from the impurity region portions 15, channel stop region portions 16 are formed between the photo-sensors 1 adjacent to each other in the vertical direction and in the vicinity of the surface of the semiconductor substrate. Like the overflow barrier region 12 or the impurity region portions 15, the channel stop region portions 16 are comprised of an impurity of the second conduction type, i.e., for example, p-type impurity regions. Incidentally, the impurity concentration in the channel stop region portions 16 is preferably higher than that in the impurity region portions 15, but this is not limitative.

In the solid state image pickup device configured as above, the channel stop region portions 16 are formed in the vicinity of the surface of the semiconductor substrate, with the result that regions having a potential of nearly 0 V are extended. Therefore, the discharge of holes accumulated in the overflow barrier region 12 to the surface of the semiconductor substrate can be achieved more effectively than in the case of the first embodiment, which contributes to prevention of the mixing of signal charges between the adjacent pixels.

### FOURTH EMBODIMENT

Now, a solid state image pickup device according to a fourth embodiment will be described below. It should be noted here that only the difference between this embodiment and the above-described first to third embodiments will be described.

FIG. 5 is a schematic diagram showing an exemplary configuration of a major part in the fourth embodiment of the solid state image pickup device according to the present invention. As shown in the figure, the solid state image pickup device described here has a configuration in which an interface in the depth direction of the overflow barrier region 12 formed on the deep layer portion side of the semiconductor substrate, i.e., on the deep layer portion side of the photo-sensors 1 and the vertical transfer transistors 2, specifically, the interface between the overflow barrier region 12 and the semiconductor region 13, is formed in a projected and recessed shape, and a projected portion in the projected and recessed shape is located at a position corresponding to a position between the photo-sensors 1. In other words, the overflow barrier region 12 is formed to be deeper in the lower layer region of each photo-sensor 1 and be shallower in the surrounding regions. Incidentally, the depth direction here means the direction of spacing away from the surface of the solid state image pickup device. The projected and recessed shape means a non-flat state, and includes not only the state of being provided with angular projected and recessed portions but also the case where the corner portions (originally angular portions) of the projected and recessed portions are moderately rounded off.

The overflow barrier region 12 having such a projected and recessed shape can be formed, for example, by a method in which an annular photoresist pattern surrounding each photo-sensor 1 is provided so as to regulate the range of Si ions implanted at the time of forming the overflow barrier region 12. The regulation of the range of the Si ions is carried out by regulating the film thickness of the photoresist.

In the solid state image pickup device configured as above, the overflow barrier region 12 having the projected and recessed shape is provided, and each projected portion in the projected and recessed shape is located at a position corresponding to a position between the photo-sensors 1, so that the projected portion functions as a sideways barrier for preventing the movement of signal charges. Therefore, the projected portions, together with the impurity region portion 15 continuing in the horizontal direction, constitute a sufficient potential barrier between the photo-sensors 1, whereby the mixing of signal charges between the adjacent pixels can be prevented more effectively than in the case of the first embodiment. In addition, since the movement of signal charges on the deep layer portion side of the semiconductor substrate is prevented, smearing which would otherwise occur through the deep layer portion can be prevented effectively, and, as a result, an enhanced image quality can be contrived.

### FIFTH EMBODIMENT

Now, a solid state image pickup device according to a fifth embodiment will be described below. It should be noted here that only the difference between this embodiment and the above-described first to fourth embodiment will be described.

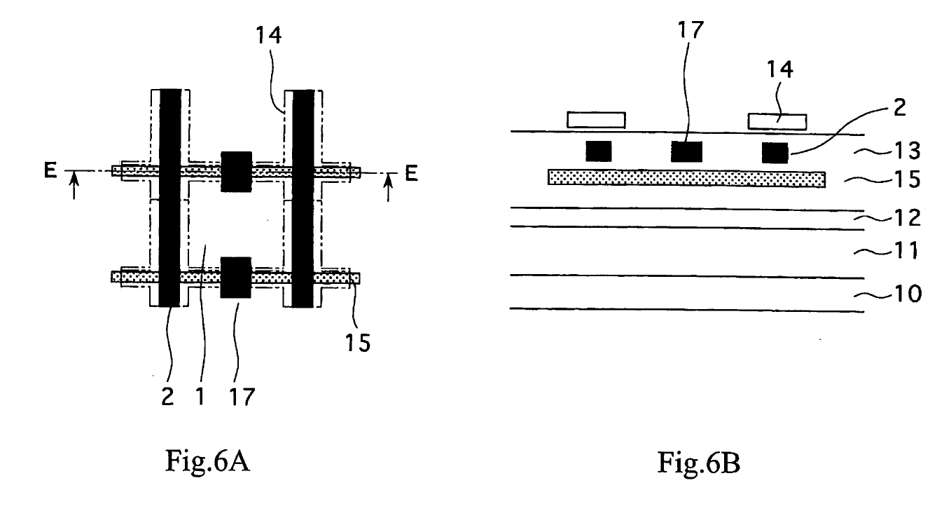

FIGS. 6A and 6B are schematic diagrams showing an exemplary configuration of a major part in the fifth embodiment of the solid state image pickup device according to the present invention. As shown in the figures, the solid state image pickup device being described here has a configuration in which, in addition to the impurity region portions 15, first barrier region portions 17 are each formed at a position between the photo-sensors 1 adjacent to each other in the vertical direction and shallower than the impurity region portions as viewed from the face layer portion side of the semiconductor substrate. Like the impurity region portions 15, the first barrier region portions 17 are each comprised of an impurity of the second conduction type, i.e., for example, a p-type impurity region. The impurity concentration in the first barrier region portions 17 may be comparable to that in the impurity region portions 15. It should be noted here that the first barrier region portions 17 are not continuous in the horizontal direction as the impurity region portions 15, but are formed in island form only at parts of the portions between the photo-sensors 1. In other words, the first barrier region portions 17 are formed at a comparatively low energy of several tens of kilo electron volt.

In the solid state image pickup device configured as above, the mixing of signal charges between the adjacent pixels can be prevented by the impurity region portions 15 formed continuously in the horizontal direction, and, in addition, since the first barrier region portions 17 present in island form, the barrier between the adjacent pixels can be further enlarged and the mixing of signal charges can be made more difficult, as compared with the case of the first embodiment. Therefore, this embodiment is particularly effective in the case where the overflow barrier region 12 is formed at a deep position for the purpose of enhancing the sensitivity. Furthermore, this embodiment is very effective also in the case where the P-type impurity concentration in the vicinity of the surface between the adjacent pixels is so low that an inconvenience might be generated. Moreover, the presence of the first barrier region portions 17 ensures that, even in the case where the overflow barrier region 12 is formed at a deep position, the discharge of the holes accumulated in the overflow barrier region 12 to the surface of the semiconductor substrate can be achieved more effectively and easily than the case of the first embodiment.

### SIXTH EMBODIMENT

Now, a solid state image pickup device according to a sixth embodiment will be described below. It should be noted here that only the difference between this embodiment and the above-described first to fifth embodiments will be described.

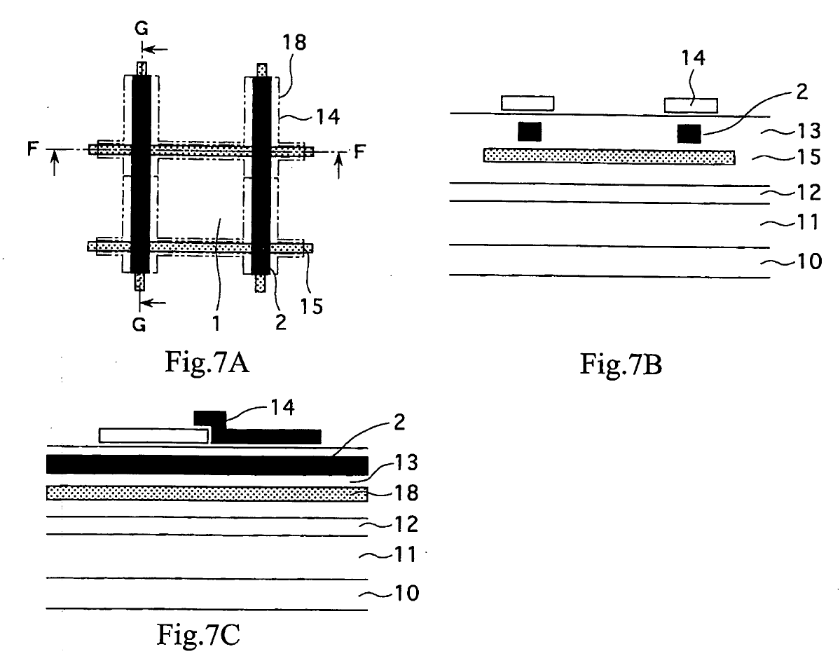

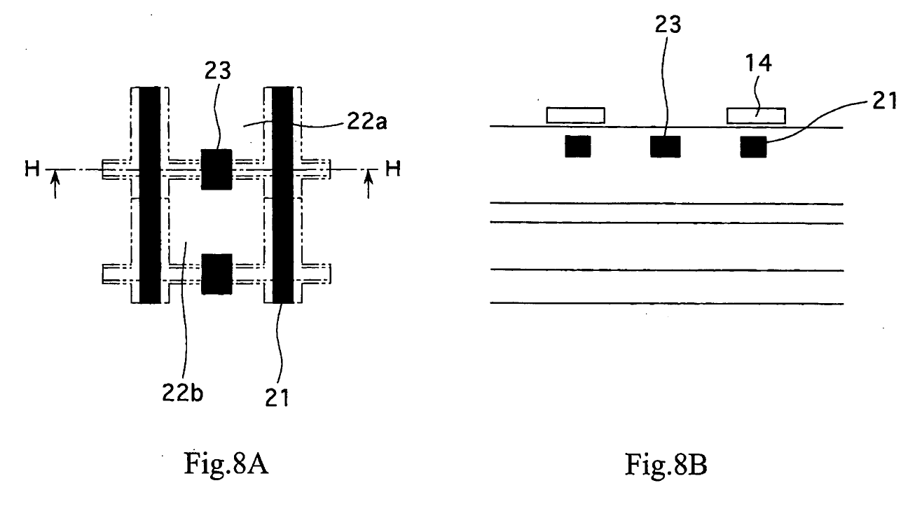

FIGS. 7A to 7C are schematic diagrams showing an exemplary configuration of a major part in the sixth embodiment of the solid state image pickup device according to the present invention. As shown in the figures, the solid state image pickup device described here has a configuration in which, in addition to the impurity region portions 15, second barrier region portions 18 continuing in the vertical direction are formed on the lower side of the vertical transfer registers 2, along the vertical transfer registers 2. Like the impurity region portions 15, the second barrier region portions 18 are each comprised of an impurity of the second conduction type, i.e., for example, a p-type impurity region.

In addition, the second barrier region portions 18 may be formed at the same depth as the impurity region portions, or may be formed at a depth different from that of the impurity region portions 15. It should be noted here that where the second barrier region portions 18 are formed at the same depth as the impurity region portions 15, the two kinds of portions can be formed by one time of ion implantation, for example, by changing the patterning from a stripe pattern to a lattice pattern at the time of implanting the ions of a p-type impurity.

In the solid state image pickup device configured as above, the second barrier region portions 18 are formed in addition to the impurity region portions 15, so that the portion of each photo-sensor 1 is surrounded by these portions. Therefore, not only the mixing of signal charges between the adjacent pixels in the vertical direction can be prevented, but also the mixing of signal charges in the horizontal direction and skew directions can also be prevented.

In addition, in the case where the second barrier region portions 18 are formed in addition to the impurity region portions 15, it may be contemplated to form the overflow barrier region 12 in the projected and recessed shape and locate each projected portion of the projected and recessed shape at a position corresponding to a position between the photo-sensors 1, as has been described in the fourth embodiment above (see FIG. 5). In this case, since the impurity regions are arranged in a lattice pattern by the impurity region portions 15 and the second barrier region portions 18 in the solid state image pickup device in this embodiment, it may be contemplated that the projected portions of the overflow barrier region 12 are also arranged in a lattice patten corresponding to the impurity region portions 15 and the second barrier region portions 18. According to such a configuration, the movements of signal charges in both the vertical and horizontal directions on the deep layer portion side of the semiconductor substrate can be prevented, so that smearing which might otherwise be generated through the deep layer portion can be prevented effectively, and, as a result, an enhanced image quality can be contrived. It should be noted here that the projected portions in the overflow barrier region 12 may naturally be arranged in a stripe pattern instead of the lattice pattern.

Incidentally, the above-described first to sixth embodiments are merely specific examples realizing the present invention, and the present invention naturally is not limited to them. For example, while the case in which the photo-sensors 1 are arranged in a two-dimensional matrix pattern and the impurity region portions 15 each continue in the horizontal direction over the range of a plurality of pixels has been taken as an example in each of the above embodiments, in the case of applying the present invention to a line type CCD sensor, an image pickup region is composed of one column of photo-sensors and a transfer register along them, so that it suffices that the barrier region portions each continue in a direction orthogonal to the transfer direction of the transfer register over roughly the entire region of the image pickup region.

Besides, while the case of applying the present invention to a CCD type image pickup device using an n-type semiconductor substrate has been taken as an example in each of the above-described first to sixth embodiments, it may be contemplated to similarly apply the present invention to other solid state image pickup devices such as, for example, CMOS (Complementary Metal Oxide Semiconductor) image sensors.

### INDUSTRIAL APPLICABILITY

As has been described above, the solid state image pickup device as set forth in claim 1 of the present invention includes the impurity region portions each formed at a position corresponding to a position between the photo-sensors and continuing over roughly the entire region of the image pickup region, so that a sufficient potential barrier can be formed between the photo-sensors. Therefore, even in the case where the overflow barrier is formed at a deep position for the purpose of enhancing the sensitivity per unit area, the mixing of signals between the adjacent pixels can be prevented, the holes accumulated in the overflow barrier can be discharged to the device surface side, and, as a result, an enhanced picked-up image quality can be contrived. This, further, promises a contribution to the reduction in size of the solid state image pickup device.

1. A solid state image pickup device having an image pickup region comprised of a plurality of photo-sensors and a transfer register for transferring signal charges accumulated in said photo-sensors, said image pickup region formed on the face layer side of a substrate, wherein said solid state image pickup device further comprises
an impurity region portion formed continuously in a direction orthogonal to the transfer direction of said transfer register, said impurity region portion provided at a position corresponding to a position between said photo-sensors adjacent to each other along the transfer direction of said transfer register in said substrate.

2. The solid state image pickup device as set forth in claim 1, wherein
said impurity region portion is formed at a position deeper than said transfer register as viewed from the face layer portion side of said substrate.

3. The solid state image pickup device as set forth in claim 1, wherein
a plurality of said impurity region portions are formed in the depth direction of said substrate.

4. The solid state image pickup device as set forth in claim 1, wherein
separately from said impurity region portion, a channel stop region portion comprised of an impurity region is formed between said photo-sensors adjacent to each other along the transfer direction of said transfer register and in the vicinity of the surface of said substrate.

5. The solid state image pickup device as set forth in claim 1, further comprising
an overflow barrier formed in said substrate on the deep layer portion side relative to said photo-sensors and said transfer register, wherein
said overflow barrier is in a projected and recessed shape at an interface thereof in the depth direction of said substrate, and a projected portion of said projected and recessed shape is disposed at a position corresponding to a position between said photo-sensors.

6. The solid state image pickup device as set forth in claim 1, wherein
in addition to said impurity region portion, a first barrier region portion comprised of an impurity region is provided at a position between said photo-sensors adjacent to each other in the transfer direction of said transfer register and shallower relative to said impurity region portion as viewed from the face layer portion side of said substrate.

7. The solid state image pickup device as set forth in claim 1, further comprising
a second barrier layer comprised of an impurity region portion formed along said transfer register.

8. The solid state image pickup device as set forth in claim 7, further comprising
an overflow barrier formed in said substrate on the deep layer portion side relative to said photo-sensors and said transfer register, wherein
said overflow barrier is in a projected and recessed shape at an interface of said photo-sensors and said transfer register side in the depth direction of said substrate, and a projected portion of said projected and recessed shape is disposed at a position corresponding to a position between said photo-sensors.

9. The solid state image pickup device as set forth in claim 5, wherein
said impurity region portion is higher than said overflow barrier in impurity concentration.

10. The solid state image pickup device as set forth in claim 8, wherein
said impurity region portion is higher than said overflow barrier in impurity concentration.

11. The solid state image pickup device as set forth in claim 7, wherein
said impurity region portion and said second barrier region portion are located at the same depth as viewed from the face layer portion side of said substrate.

12. A solid state image pickup device having an image pickup region comprised of a plurality of photo-sensors and a transfer register for transferring signal charges accumulated in said photo-sensors, said image pickup region formed on the face layer portion side of a substrate, wherein said solid image pickup device further comprises
an impurity region portion formed in said substrate continuously with a position between said photo-sensors adjacent to each other in the transfer direction of said transfer register.

13. The solid state image pickup device as set forth in claim 12, wherein
said impurity region portion is formed at a position deeper than said transfer register as viewed from the face layer portion side of said substrate.

14. The solid state image pickup device as set forth in claim 12, further comprising
a second barrier region portion comprised of an impurity region formed along said transfer register.

15. A method of manufacturing a solid state image pickup device, comprising the steps of:
forming on the face layer portion side of a substrate a plurality of photo-sensors and a transfer register for transferring signal charges accumulated in said photo-sensors; and
forming an impurity region portion continuously in said substrate at a position between said photo-sensors adjacent to each other along the transfer direction of said transfer register.

16. The method of manufacturing a solid state image pickup device as set forth in claim 15, wherein
said impurity region portion is formed at a position deeper than said transfer register as viewed from the face layer portion side of said substrate.

17. The method of manufacturing a solid state image pickup device as set forth in claim 15, wherein
a plurality of said impurity region portions are formed in the depth direction of said substrate.

18. The method of manufacturing a solid state image pickup device as set forth in claim 15, further comprising the step of
forming an overflow barrier in said substrate on the deep layer portion side relative to said photo-sensors and said transfer register, wherein
said overflow barrier is in a projected and recessed shape at an interface thereof in the depth direction of said substrate, and a projected portion of said projected and recessed shape is disposed at a position corresponding to a position between said photo-sensors.

19. The method of manufacturing a solid state image pickup device as set forth in claim 15, further comprising the step of
forming a first barrier region portion comprised of an impurity region at a position between said photo-sensors adjacent to each other along the transfer direction of said transfer register and deeper than said impurity region portion as viewed from the face layer portion side of said substrate.

20. The method of manufacturing a solid state image pickup device as set forth in claim 15, further comprising the step of
forming a second barrier region portion comprised of an impurity region along said transfer region.
